(19) United States
(12) Patent Application Publication
(10) Pub. No.: US 2019/0103883 A1
(43) Pub. Date: Apr. 4, 2019

(54) JOINT SOURCE AND POLAR CODING

(71) Applicant: IDAC Holdings, Inc., Wilmington, DE (US)

(72) Inventors: Chunxuan Ye, San Diego, CA (US); Fengjun Xi, San Diego, CA (US); Kyle Jung-Lin Pan, Saint James, NY (US)

(73) Assignee: IDAC Holdings, Inc., Wilmington, DE (US)

(21) Appl. No.: 16/087,256

(22) PCT Filed: Mar. 28, 2017
(86) PCT No.: PCT/US2017/024452

§ 371 Date: Sep. 21, 2018

Related U.S. Application Data
(60) Provisional application No. 62/315,183, filed on Mar. 30, 2016.

(51) Int. Cl. H03M 13/13; H03M 13/35; H04B 7/0456; H03M 13/00; H04L 1/00

(52) U.S. Cl. CPC H03M 13/13; H03M 13/356; H04B 7/0456; H04L 1/0057; H04L 1/007; H04L 1/0009; H04L 1/0042; H03M 13/6312

(57) ABSTRACT

Systems, methods, and instrumentalities are disclosed for joint source and polar coding. Source bits may be received and/or ordered based on the priorities of the source bits. The ordered source bits may be grouped. For example, the source bits may be grouped into one or more blocks. The ordered source bits may be distributed among the one or more blocks. For example, the ordered source bits may be distributed among the one or more blocks based on priorities of the ordered source bits. The ordered source bits may be mapped to polar coder ports. For example, the ordered source bits may be mapped to the polar coder ports based on a reliability of the polar codes of the ordered source bits. The transmitter may transmit the mapped ordered source bits of the one or more blocks. Polar encoding of the respective mapped ordered source bits may be performed.

### CROSS-REFERENCE

This application claims the benefit of U.S. Provisional Application No. 62/315,183 filed on Mar. 30, 2016, which is incorporated herein by reference as if fully set forth.

### BACKGROUND

Mobile communications continue to evolve. A fifth generation may be referred to as 5G. A previous (legacy) generation of mobile communication may be, for example, fourth generation (4G) long term evolution (LTE). Mobile wireless communications implement a variety of radio access technologies (RATs), such as New Radio (NR). Current coding techniques suffer from deficiencies.

### SUMMARY

Systems, methods, and instrumentalities are disclosed for joint source and polar coding. Polar coding of one or more prioritized source bits (e.g., such as progressive images, scalable video, and/or the like) may be provided. Combining may be performed at a channel coding level for a transmission (e.g., such as a multi-user superposition transmission (MUST)). Link adaptive polar coding may be performed. A coding rate for a multi-user joint source polar coding may be determined. Modulation may be performed for the multi-user joint source polar coding.

Source bits may be received. The source bits may be associated with different priority levels. The source bits may be un-ordered. The source bits may be re-ordered based on the respective priorities associated with the source bits. One or more of the source bits (e.g., a block of source bits) may be selected as an input to a polar encoder. The one or more selected source bits may be bit-mapped to the polar encoder. The one or more selected source bits may be encoded to generate one or more coded bits. Rate matching may be applied to the one or more coded bits. Constellation mapping may be applied to the one or more coded bits. Layer mapping may be applied to the one or more coded bits. Precoding may be applied to the one or more coded bits.

For example, a transmitter may order the source bits based on the priorities of the source bits. The transmitter may group the ordered source bits. For example, the transmitter may group the ordered source bits into one or more blocks. The ordered source bits may be distributed among the one or more blocks. For example, the ordered source bits may be distributed among the one or more blocks based on priorities of the ordered source bits. The transmitter may map the ordered source bits of the one or more blocks to polar coder ports. The ordered source bits may be mapped to the polar coder ports based on a reliability. For example, the ordered source bits may be mapped to the polar coder ports based on a reliability of the polar codes of the ordered source bits. The transmitter may transmit the mapped ordered source bits of the one or more blocks.

A higher priority source bit in a block may be more protected than a lower priority source bit in the block. Polar encoding of the respective mapped ordered source bits may be performed. The higher priority source bit in the block may be more protected than the lower priority source bit in the block. For example, the higher priority source bit in the block may be more protected than the lower priority source bit in the block based on the higher priority source bit being polar encoded to a higher capacity channel than the lower priority source bit.

The source bits may include first source bits of a first user and second source bits of a second user. The transmitter may order the first source bits of the first user and/or the second source bits of the second user. For example, the first source bits of the first user and/or the second source bits of the second user may be ordered based on priorities of the first source bits and/or the second source bits. The first ordered source bits and/or the second ordered source bits may be grouped. For example, the first ordered source bits may be grouped into one or more first blocks and/or the second ordered source bits may be grouped into one or more second blocks. The first ordered source bits may be distributed among the one or more first blocks based on the priorities of the first ordered source bits. The second ordered source bits may be distributed among the second blocks based on the priorities of the second ordered source bits.

The transmitter may map first ordered source bits and/or second ordered source bits. For example, the transmitter may map first ordered source bits and/or second ordered source bits to polar coder ports. The first ordered source bits and/or the second ordered source bits may be mapped to the polar coder ports based on a reliability of polar codes of the first ordered source bits and/or the second ordered source bits. The transmitter may perform polar encoding of the mapped first ordered source bits and the mapped second ordered source bits.

### BRIEF DESCRIPTION OF THE DRAWINGS

FIG. 1A is a system diagram of an example communications system in which one or more disclosed embodiments may be implemented.

FIG. 1B is a system diagram of an example wireless transmit/receive unit (WTRU) that may be used within the communications system illustrated in FIG. 1A.

FIG. 1C is a system diagram of an example radio access network and an example core network that may be used within the communications system illustrated in FIG. 1A.

FIG. 1D is a system diagram of another example radio access network and an example core network that may be used within the communications system illustrated in FIG. 1A.

FIG. 1E is a system diagram of another example radio access network and an example core network that may be used within the communications system illustrated in FIG. 1A.

FIG. 1F illustrates exemplary wireless local area network (WLAN) devices.

FIG. 2 depicts an example channel polarization.

FIG. 3 depicts an example combining using a vector channel.

FIG. 4 depicts an example splitting using a vector channel.

FIG. 5 depicts an example Multi-User Superposition Transmission (MUST) with combining performed at a codeword level.

FIG. 6 depicts an example MUST with combining performed at a modulation mapping level.

FIG. 7 depicts an example MUST with combining performed at a spatial layer level.

FIG. 8 depicts an example MUST with combining performed after MIMO precoding.

FIG. 9 depicts an example polar code.

FIG. 10 depicts an example polar encoder applied on one or more source bits with priorities.

FIG. 11 depicts an example polar decoding of one or more source bits with priorities.

FIG. 12 depicts an example combining at a channel coding level.

FIG. 13 depicts an example detailed multi-user combiner and polar encoder.

FIG. 14 depicts an example detailed multi-user data separator and polar decoder.

### DETAILED DESCRIPTION

A detailed description of illustrative embodiments will now be described with reference to the various Figures. Although this description provides a detailed example of possible implementations, it should be noted that the details are intended to be exemplary and in no way limit the scope of the application.

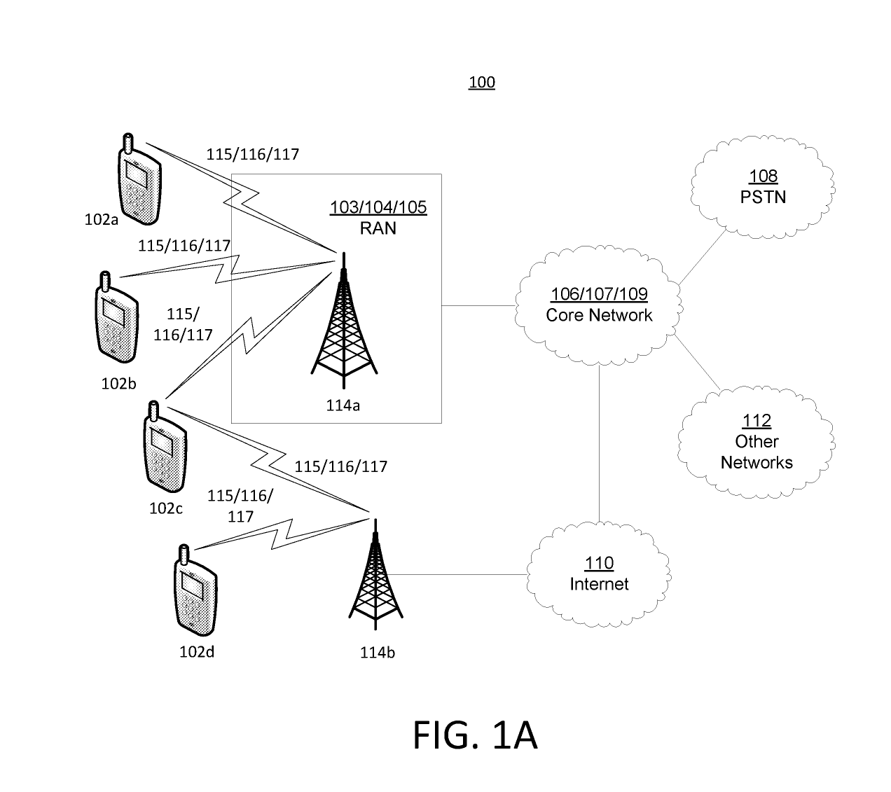

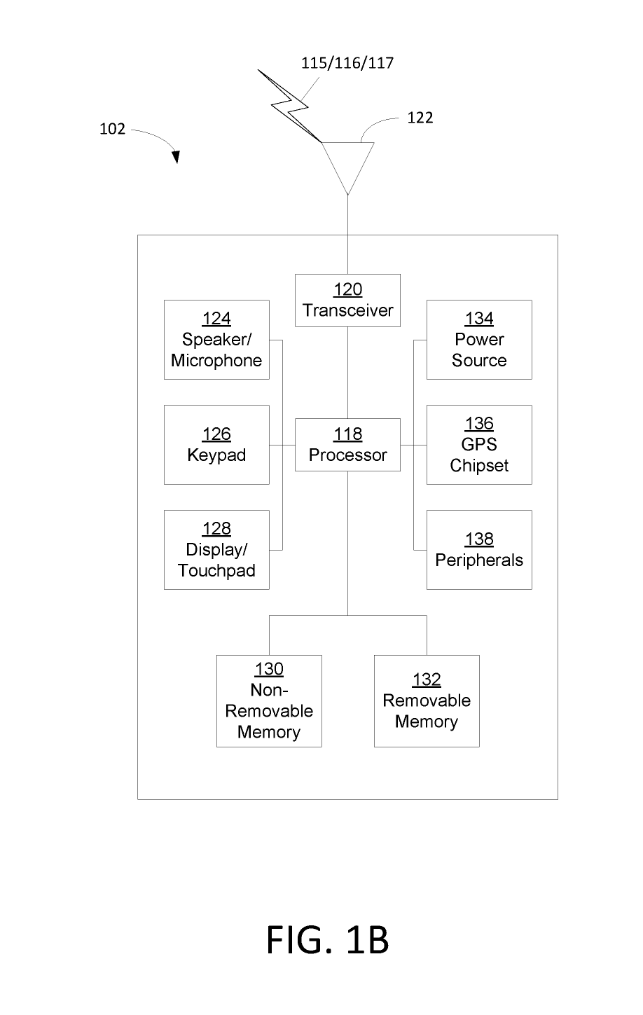

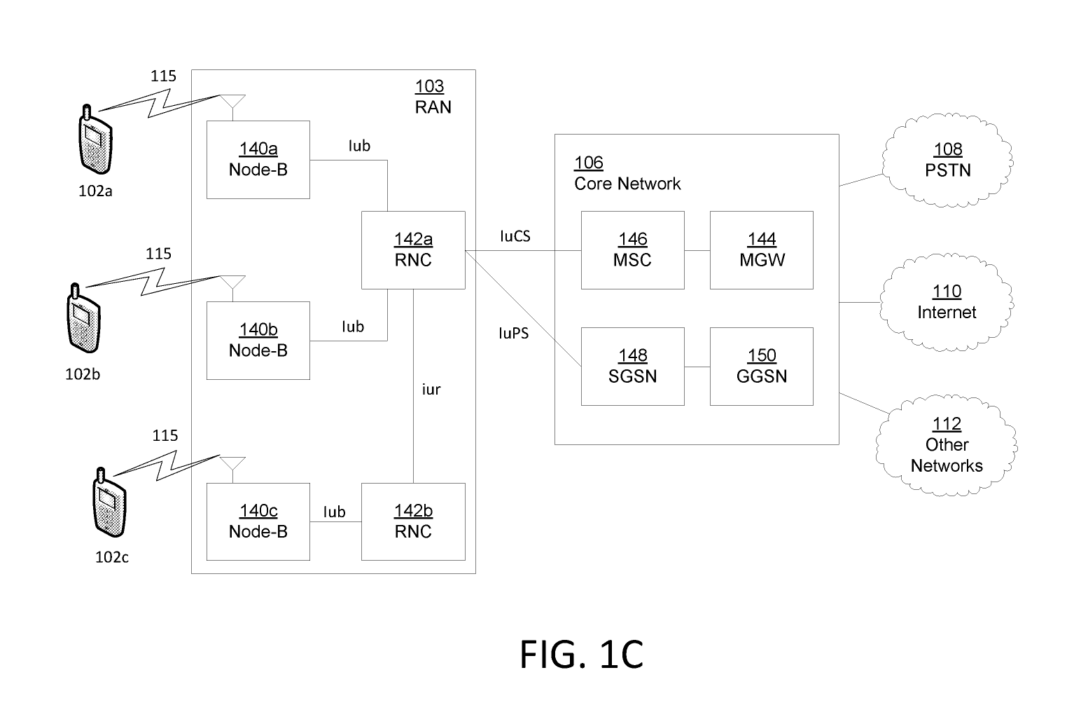

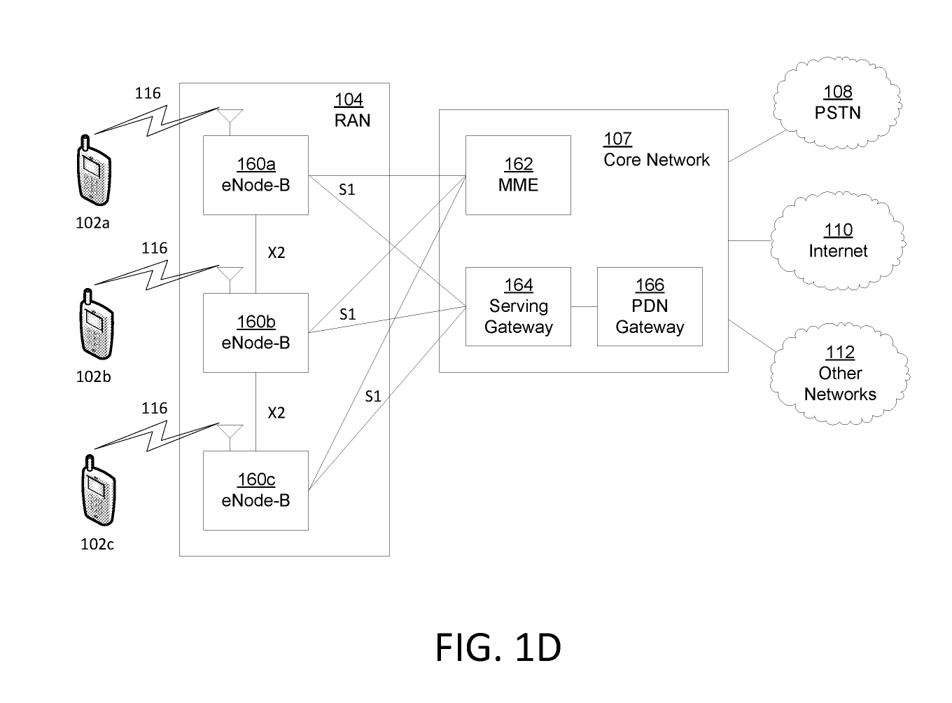

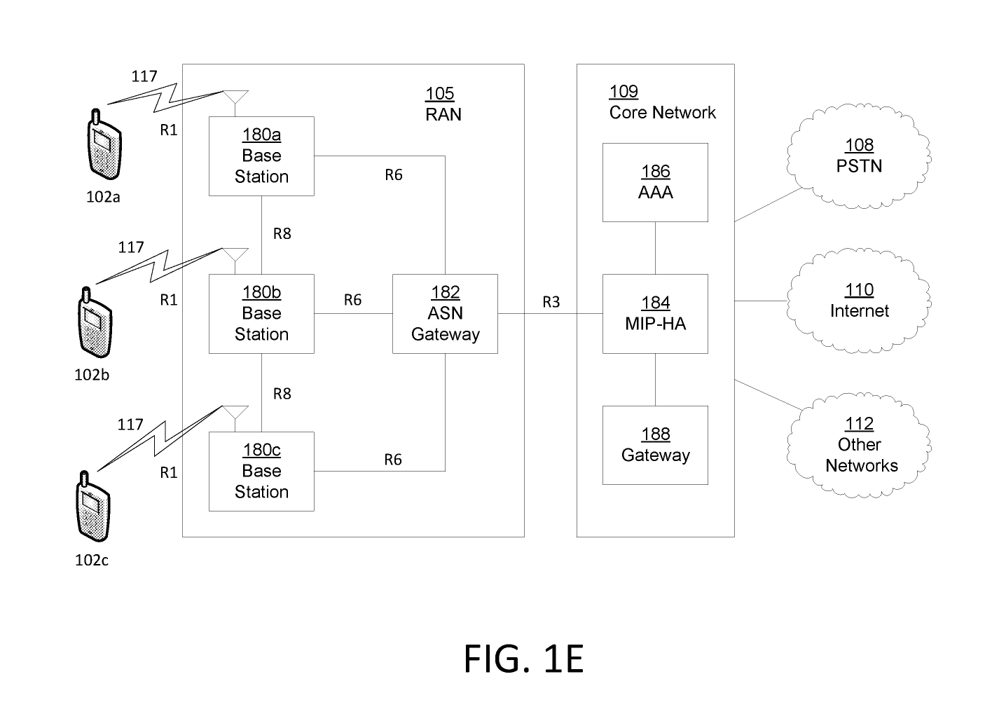

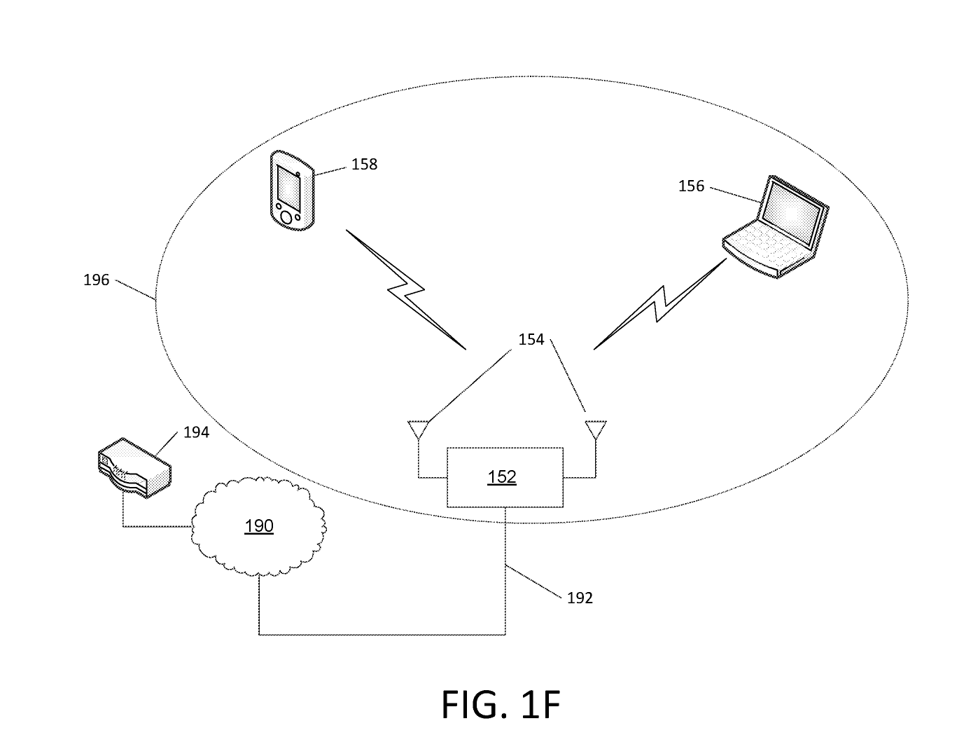

FIG. 1A is a diagram of an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), and the like.

As shown in FIG. 1A, the communications system 100 may include wireless transmit/receive units (WTRUs) 102a, 102b, 102c, and/or 102d (which generally or collectively may be referred to as WTRU 102), a radio access network (RAN) 103/104/105, a core network 106/107/109, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d may be configured to transmit and/or receive wireless signals and may include user equipment (UE), a mobile station, a fixed or mobile subscriber unit, a pager, a cellular telephone, a personal digital assistant (PDA), a smartphone, a laptop, a netbook, a personal computer, a wireless sensor, consumer electronics, and the like.

The communications systems 100 may also include a base station 114a and a base station 114b. Each of the base stations 114a, 114b may be any type of device configured to wirelessly interface with at least one of the WTRUs 102a, 102b, 102c, 102d to facilitate access to one or more communication networks, such as the core network 106/107/109, the Internet 110, and/or the networks 112. By way of example, the base stations 114a, 114b may be a base transceiver station (BTS), a Node-B, an eNode B, a Home Node B, a Home eNode B, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 103/104/105, which may also include other base stations and/or network elements (not shown), such as a base station controller (BSC), a radio network controller (RNC), relay nodes, etc. The base station 114a and/or the base station 114b may be configured to transmit and/or receive wireless signals within a particular geographic region, which may be referred to as a cell (not shown). The cell may further be divided into cell sectors. For example, the cell associated with the base station 114a may be divided into three sectors. Thus, in one embodiment, the base station 114a may include three transceivers, e.g., one for each sector of the cell. In another embodiment, the base station 114a may employ multiple-input multiple output (MIMO) technology and, therefore, may utilize multiple transceivers for each sector of the cell.

The base stations 114a, 114b may communicate with one or more of the WTRUs 102a, 102b, 102c, 102d over an air interface 115/116/117, which may be any suitable wireless communication link (e.g., radio frequency (RF), microwave, infrared (IR), ultraviolet (UV), visible light, etc.). The air interface 115/116/117 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 103/104/105 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink Packet Access (HSDPA) and/or High-Speed Uplink Packet Access (HSUPA).

In another embodiment, the base station 114a and the WTRUs 102a, 102b, 102c may implement a radio technology such as Evolved UMTS Terrestrial Radio Access (E-UTRA), which may establish the air interface 115/116/117 using Long Term Evolution (LTE) and/or LTE-Advanced (LTE-A).

In other embodiments, the base station 114a and the WTRUs 102a, 102b, 102c may implement radio technologies such as IEEE 802.16 (e.g., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, and the like. In one embodiment, the base station 114b and the WTRUs 102c, 102d may implement a radio technology such as IEEE 802.11 to establish a wireless local area network (WLAN). In another embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, etc.) to establish a picocell or femtocell. As shown in FIG. 1A, the base station 114b may have a direct connection to the Internet 110. Thus, the base station 114b may not be required to access the Internet 110 via the core network 106/107/109.

The RAN 103/104/105 may be in communication with the core network 106/107/109, which may be any type of network configured to provide voice, data, applications, and/or voice over internet protocol (VoIP) services to one or more of the WTRUs 102a, 102b, 102c, 102d. For example, the core network 106/107/109 may provide call control, billing services, mobile location-based services, pre-paid calling, Internet connectivity, video distribution, etc., and/or perform high-level security functions, such as user authentication. Although not shown in FIG. 1A, it will be appreciated that the RAN 103/104/105 and/or the core network 106/107/109 may be in direct or indirect communication with other RANs that employ the same RAT as the RAN 103/104/105 or a different RAT. For example, in addition to being connected to the RAN 103/104/105, which may be utilizing an E-UTRA radio technology, the core network 106/107/109 may also be in communication with another RAN (not shown) employing a GSM radio technology.

The core network 106/107/109 may also serve as a gateway for the WTRUs 102a, 102b, 102c, 102d to access the PSTN 108, the Internet 110, and/or other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and the internet protocol (IP) in the TCP/IP internet protocol suite. The networks 112 may include wired or wireless communications networks owned and/or operated by other service providers. For example, the networks 112 may include another core network connected to one or more RANs, which may employ the same RAT as the RAN 103/104/105 or a different RAT.

Some or all of the WTRUs 102a, 102b, 102c, 102d in the communications system 100 may include multi-mode capabilities, e.g., the WTRUs 102a, 102b, 102c, 102d may include multiple transceivers for communicating with different wireless networks over different wireless links. For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram of an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and other peripherals 138. It will be appreciated that the WTRU 102 may include any sub-combination of the foregoing elements while remaining consistent with an embodiment. Also, embodiments contemplate that the base stations 114a and 114b, and/or the nodes that base stations 114a and 114b may represent, such as but not limited to transceiver station (BTS), a Node-B, a site controller, an access point (AP), a home node-B, an evolved node-B (eNodeB), a home evolved node-B (HeNB), a g node-B (gNB), a home evolved node-B gateway, and proxy nodes, among others, may include some or all of the elements depicted in FIG. 1B and described herein.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 115/116/117. For example, in one embodiment, the transmit/receive element 122 may be an antenna configured to transmit and/or receive RF signals. In another embodiment, the transmit/receive element 122 may be an emitter/detector configured to transmit and/or receive IR, UV, or visible light signals, for example. In yet another embodiment, the transmit/receive element 122 may be configured to transmit and receive both RF and light signals. It will be appreciated that the transmit/receive element 122 may be configured to transmit and/or receive any combination of wireless signals.

In addition, although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 115/116/117.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as UTRA and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 115/116/117 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs or video), a universal serial bus (USB) port, a vibration device, a television transceiver, a hands free headset, a Bluetooth® module, a frequency modulated (FM) radio unit, a digital music player, a media player, a video game player module, an Internet browser, and the like.

FIG. 1C is a system diagram of the RAN 103 and the core network 106 according to an embodiment. As noted above, the RAN 103 may employ a UTRA radio technology to communicate with the WTRUs 102a, 102b, 102c over the air interface 115. The RAN 103 may also be in communication with the core network 106. As shown in FIG. 1C, the RAN 103 may include Node-Bs 140a, 140b, 140c, which may each include one or more transceivers for communicating with the WTRUs 102a, 102b, 102c over the air interface 115. The Node-Bs 140a, 140b, 140c may each be associated with a particular cell (not shown) within the RAN 103. The RAN 103 may also include RNCs 142a, 142b. It will be appreciated that the RAN 103 may include any number of Node-Bs and RNCs while remaining consistent with an embodiment.

As shown in FIG. 1C, the Node-Bs 140a, 140b may be in communication with the RNC 142a. Additionally, the Node-B 140c may be in communication with the RNC 142b. The Node-Bs 140a, 140b, 140c may communicate with the respective RNCs 142a, 142b via an Iub interface. The RNCs 142a, 142b may be in communication with one another via an Iur interface. Each of the RNCs 142a, 142b may be configured to control the respective Node-Bs 140a, 140b, 140c to which it is connected. In addition, each of the RNCs 142a, 142b may be configured to carry out or support other functionality, such as outer loop power control, load control, admission control, packet scheduling, handover control, macrodiversity, security functions, data encryption, and the like.

The core network 106 shown in FIG. 1C may include a media gateway (MGW) 144, a mobile switching center (MSC) 146, a serving GPRS support node (SGSN) 148, and/or a gateway GPRS support node (GGSN) 150. While each of the foregoing elements are depicted as part of the core network 106, it will be appreciated that any one of these elements may be owned and/or operated by an entity other than the core network operator.

The RNC 142a in the RAN 103 may be connected to the MSC 146 in the core network 106 via an IuCS interface. The MSC 146 may be connected to the MGW 144. The MSC 146 and the MGW 144 may provide the WTRUs 102a, 102b, 102c with access to circuit-switched networks, such as the PSTN 108, to facilitate communications between the WTRUs 102a, 102b, 102c and traditional land-line communications devices.

The RNC 142a in the RAN 103 may also be connected to the SGSN 148 in the core network 106 via an IuPS interface. The SGSN 148 may be connected to the GGSN 150. The SGSN 148 and the GGSN 150 may provide the WTRUs 102a, 102b, 102c with access to packet-switched networks, such as the Internet 110, to facilitate communications between and the WTRUs 102a, 102b, 102c and IP-enabled devices.

As noted above, the core network 106 may also be connected to the networks 112, which may include other wired or wireless networks that are owned and/or operated by other service providers.

FIG. 1D is a system diagram of the RAN 104 and the core network 107 according to an embodiment. As noted above, the RAN 104 may employ an E-UTRA radio technology to communicate with the WTRUs 102a, 102b, 102c over the air interface 116. The RAN 104 may also be in communication with the core network 107.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and receive wireless signals from, the WTRU 102a.

Each of the eNode-Bs 160a, 160b, 160c may be associated with a particular cell (not shown) and may be configured to handle radio resource management decisions, handover decisions, scheduling of users in the uplink and/or downlink, and the like. As shown in FIG. 1D, the eNode-Bs 160a, 160b, 160c may communicate with one another over an X2 interface.

The core network 107 shown in FIG. 1D may include a mobility management gateway (MME) 162, a serving gateway 164, and a packet data network (PDN) gateway 166. While each of the foregoing elements are depicted as part of the core network 107, it will be appreciated that any one of these elements may be owned and/or operated by an entity other than the core network operator.

The MME 162 may be connected to each of the eNode-Bs 160a, 160b, 160c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may also provide a control plane function for switching between the RAN 104 and other RANs (not shown) that employ other radio technologies, such as GSM or WCDMA.

The serving gateway 164 may be connected to each of the eNode-Bs 160a, 160b, 160c in the RAN 104 via the S1 interface. The serving gateway 164 may generally route and forward user data packets to/from the WTRUs 102a, 102b, 102c. The serving gateway 164 may also perform other functions, such as anchoring user planes during inter-eNode B handovers, triggering paging when downlink data is available for the WTRUs 102a, 102b, 102c, managing and storing contexts of the WTRUs 102a, 102b, 102c, and the like.

The serving gateway 164 may also be connected to the PDN gateway 166, which may provide the WTRUs 102a, 102b, 102c with access to packet-switched networks, such as the Internet 110, to facilitate communications between the WTRUs 102a, 102b, 102c and IP-enabled devices.

The core network 107 may facilitate communications with other networks. For example, the core network 107 may provide the WTRUs 102a, 102b, 102c with access to circuit-switched networks, such as the PSTN 108, to facilitate communications between the WTRUs 102a, 102b, 102c and traditional land-line communications devices. For example, the core network 107 may include, or may communicate with, an IP gateway (e.g., an IP multimedia subsystem (IMS) server) that serves as an interface between the core network 107 and the PSTN 108. In addition, the core network 107 may provide the WTRUs 102a, 102b, 102c with access to the networks 112, which may include other wired or wireless networks that are owned and/or operated by other service providers.

FIG. 1E is a system diagram of the RAN 105 and the core network 109 according to an embodiment. The RAN 105 may be an access service network (ASN) that employs IEEE 802.16 radio technology to communicate with the WTRUs 102a, 102b, 102c over the air interface 117. As will be further discussed below, the communication links between the different functional entities of the WTRUs 102a, 102b, 102c, the RAN 105, and the core network 109 may be defined as reference points.

As shown in FIG. 1E, the RAN 105 may include base stations 180a, 180b, 180c, and an ASN gateway 182, though it will be appreciated that the RAN 105 may include any number of base stations and ASN gateways while remaining consistent with an embodiment. The base stations 180a, 180b, 180c may each be associated with a particular cell (not shown) in the RAN 105 and may each include one or more transceivers for communicating with the WTRUs 102a, 102b, 102c over the air interface 117. In one embodiment, the base stations 180a, 180b, 180c may implement MIMO technology. Thus, the base station 180a, for example, may use multiple antennas to transmit wireless signals to, and receive wireless signals from, the WTRU 102a. The base stations 180a, 180b, 180c may also provide mobility management functions, such as handoff triggering, tunnel establishment, radio resource management, traffic classification, quality of service (QoS) policy enforcement, and the like. The ASN gateway 182 may serve as a traffic aggregation point and may be responsible for paging, caching of subscriber profiles, routing to the core network 109, and the like.

The air interface 117 between the WTRUs 102a, 102b, 102c and the RAN 105 may be defined as an R1 reference point that implements the IEEE 802.16 specification. In addition, each of the WTRUs 102a, 102b, 102c may establish a logical interface (not shown) with the core network 109. The logical interface between the WTRUs 102a, 102b, 102c and the core network 109 may be defined as an R2 reference point, which may be used for authentication, authorization, IP host configuration management, and/or mobility management.

The communication link between each of the base stations 180a, 180b, 180c may be defined as an R8 reference point that includes protocols for facilitating WTRU handovers and the transfer of data between base stations. The communication link between the base stations 180a, 180b, 180c and the ASN gateway 182 may be defined as an R6 reference point. The R6 reference point may include protocols for facilitating mobility management based on mobility events associated with each of the WTRUs 102a, 102b, 102c.

As shown in FIG. 1E, the RAN 105 may be connected to the core network 109. The communication link between the RAN 105 and the core network 109 may defined as an R3 reference point that includes protocols for facilitating data transfer and mobility management capabilities, for example. The core network 109 may include a mobile IP home agent (MIP-HA) 184, an authentication, authorization, accounting (AAA) server 186, and a gateway 188. While each of the foregoing elements are depicted as part of the core network 109, it will be appreciated that any one of these elements may be owned and/or operated by an entity other than the core network operator.

The MIP-HA may be responsible for IP address management, and may enable the WTRUs 102a, 102b, 102c to roam between different ASNs and/or different core networks. The MIP-HA 184 may provide the WTRUs 102a, 102b, 102c with access to packet-switched networks, such as the Internet 110, to facilitate communications between the WTRUs 102a, 102b, 102c and IP-enabled devices. The AAA server 186 may be responsible for user authentication and for supporting user services. The gateway 188 may facilitate interworking with other networks. For example, the gateway 188 may provide the WTRUs 102a, 102b, 102c with access to circuit-switched networks, such as the PSTN 108, to facilitate communications between the WTRUs 102a, 102b, 102c and traditional land-line communications devices. In addition, the gateway 188 may provide the WTRUs 102a, 102b, 102c with access to the networks 112, which may include other wired or wireless networks that are owned and/or operated by other service providers.

Although not shown in FIG. 1E, it will be appreciated that the RAN 105 may be connected to other ASNs and the core network 109 may be connected to other core networks. The communication link between the RAN 105 the other ASNs may be defined as an R4 reference point, which may include protocols for coordinating the mobility of the WTRUs 102a, 102b, 102c between the RAN 105 and the other ASNs. The communication link between the core network 109 and the other core networks may be defined as an R5 reference, which may include protocols for facilitating interworking between home core networks and visited core networks.

FIG. 1F illustrates exemplary wireless local area network (WLAN) devices. One or more of the devices may be used to implement one or more of the features described herein. The WLAN may include, but is not limited to, access point (AP) 152, station (STA) 156, and STA 158. STA 156 and 158 may be associated with AP 152. The WLAN may be configured to implement one or more protocols of the IEEE 802.11 communication standard, which may include a channel access scheme, such as DSSS, OFDM, OFDMA, etc. A WLAN may operate in a mode, e.g., an infrastructure mode, an ad-hoc mode, etc.

A WLAN operating in an infrastructure mode may include one or more APs communicating with one or more associated STAs. An AP and STA(s) associated with the AP may include a basic service set (BSS). For example, AP 152, STA 156, and STA 158 may include BSS 196. An extended service set (ESS) may include one or more APs (with one or more BSSs) and STA(s) associated with the APs. An AP may have access to, and/or interface to, distribution system (DS) 192, which may be wired and/or wireless and may carry traffic to and/or from the AP. Traffic to a STA in the WLAN originating from outside the WLAN may be received at an AP in the WLAN, which may send the traffic to the STA in the WLAN. Traffic originating from a STA in the WLAN to a destination outside the WLAN, e.g., to server 194, may be sent to an AP in the WLAN, which may send the traffic to the destination, e.g., via DS 192 to network 190 to be sent to server 194. Traffic between STAs within the WLAN may be sent through one or more APs. For example, a source STA (e.g., STA 156) may have traffic intended for a destination STA (e.g., STA 158). STA 156 may send the traffic to AP 152, and, AP 152 may send the traffic to STA 158.

A WLAN may operate in an ad-hoc mode. The ad-hoc mode WLAN may be referred to as independent basic service set (IBBS). In an ad-hoc mode WLAN, the STAs may communicate directly with each other (e.g., STA 156 may communicate with STA 158 without such communication being routed through an AP).

IEEE 802.11 devices (e.g., IEEE 802.11 APs in a BSS) may use beacon frames to announce the existence of a WLAN network. An AP, such as AP 102, may transmit a beacon on a channel, e.g., a fixed channel, such as a primary channel. A STA may use a channel, such as the primary channel, to establish a connection with an AP.

STA(s) and/or AP(s) may use a Carrier Sense Multiple Access with Collision Avoidance (CSMA/CA) channel access mechanism. In CSMA/CA, a STA and/or an AP may sense the primary channel. For example, if a STA has data to send, the STA may sense the primary channel. If the primary channel is detected to be busy, the STA may back off. For example, a WLAN or portion thereof may be configured so that one STA may transmit at a given time, e.g., in a given BSS. Channel access may include request to send (RTS) and/or clear to send (CTS) signaling. For example, an exchange of an RTS frame may be transmitted by a sending device and a CTS frame that may be sent by a receiving device. If an AP has data to send to a STA, the AP may send an RTS frame to the STA. If the STA is ready to receive data, the STA may respond with a CTS frame. The CTS frame may include a time value that may alert other STAs to hold off from accessing the medium while the AP initiating the RTS may transmit its data. On receiving the CTS frame from the STA, the AP may send the data to the STA.

A device may reserve spectrum via a network allocation vector (NAV) field. For example, in an IEEE 802.11 frame, the NAV field may be used to reserve a channel for a time period. A STA that wants to transmit data may set the NAV to the time for which it may expect to use the channel. When a STA sets the NAV, the NAV may be set for an associated WLAN or subset thereof (e.g., a BSS). Other STAs may count down the NAV to zero. When the counter reaches a value of zero, the NAV functionality may indicate to the other STA that the channel is available.

The devices in a WLAN, such as an AP or STA, may include one or more of the following: a processor, a memory, a radio receiver and/or transmitter (e.g., which may be combined in a transceiver), one or more antennas (e.g., antennas 154 in FIG. 1F), etc. A processor function may comprise one or more processors. For example, the processor may comprise one or more of: a general purpose processor, a special purpose processor (e.g., a baseband processor, a MAC processor, etc.), a digital signal processor (DSP), Application Specific Integrated Circuits (ASICs), Field Programmable Gate Array (FPGAs) circuits, any other type of integrated circuit (IC), a state machine, and the like. The one or more processors may be integrated or not integrated with each other. The processor (e.g., the one or more processors or a subset thereof) may be integrated with one or more other functions (e.g., other functions such as memory). The processor may perform signal coding, data processing, power control, input/output processing, modulation, demodulation, and/or any other functionality that may enable the device to operate in a wireless environment, such as the WLAN of FIG. 1F. The processor may be configured to execute processor executable code (e.g., instructions) including, for example, software and/or firmware instructions. For example, the processer may be configured to execute computer readable instructions included on one or more of the processor (e.g., a chipset that includes memory and a processor) or memory. Execution of the instructions may cause the device to perform one or more of the functions described herein.

A device may include one or more antennas. The device may employ multiple input multiple output (MIMO) techniques. The one or more antennas may receive a radio signal. The processor may receive the radio signal, e.g., via the one or more antennas. The one or more antennas may transmit a radio signal (e.g., based on a signal sent from the processor).

The device may have a memory that may include one or more devices for storing programming and/or data, such as processor executable code or instructions (e.g., software, firmware, etc.), electronic data, databases, or other digital information. The memory may include one or more memory units. One or more memory units may be integrated with one or more other functions (e.g., other functions included in the device, such as the processor). The memory may include a read-only memory (ROM) (e.g., erasable programmable read only memory (EPROM), electrically erasable programmable read only memory (EEPROM), etc.), random access memory (RAM), magnetic disk storage media, optical storage media, flash memory devices, and/or other non-transitory computer-readable media for storing information. The memory may be coupled to the processer. The processer may communicate with one or more entities of memory, e.g., via a system bus, directly, etc.

Joint source-channel coding may be performed. For example, joint source-channel coding may be performed through rate-distortion curves. The one or more rate-distortion curves may control one or more channel coding rates. For example, the one or more rate-distortion curves may control one or more channel coding rates based on a compression rate. Joint source-channel coding may not be applied in many wireless communication systems. This may be due to source coding and channel coding being implemented at different communication layers in a wireless communication system. The source coding may include functionality above the transport layer. The channel coding may include functionality at the physical layer. A device performing source coding may be different than a device performing channel coding. For example, a mobile phone may attempt to download a file (e.g., video, image or text) from a cellular network. The file may be source encoded at a data server. The channel coding may be performed at a base station.

In some situations, additional information about source codes may be known at the implementing device performing channel coding. For example, for progressive encoded images, a front part of a source bitstream may be more important than a latter part of the source bitstream. For example, as the errors in the front part of the source bitstream may render the remainder of the bitstream useless, the front part of the source bitstream may be more important than a latter part of the source bitstream. As another example, one or more bits containing parameter information in a scalable video stream may be more important than one or more other bits. For the more important source bits, more protection may be required to satisfy a quality of service.

Polar coding may be performed. A polar code may be a capacity achieving code. For example, a polar code may belong to a linear block code. The polar code may include low encoding and/or decoding complexity. The polar code may include a low error floor and/or an explicit construction scheme.

Polar coding may include determining N different channels Wᵢ, 1≤i≤N from N independent copies of Binary Discrete Memoryless Channel (B-DMC) through linear transformation. For a large N, one or more synthesized channels may be polarized (e.g., capacity I(Wᵢ) is close to either 0 or 1). A first synthesized channel of the one or more synthesized channels may include mutual information close to 0. The first synthesized channel may be determined to be a bad channel. A second synthesized channel of the one or more synthesized channels may include mutual information close to 1. The second synthesized channel may be determined to be a good channel. A fraction of good channels may be represented as I(W). Better unsynthesized channels may result in more good channels. One or more data transmissions may be performed on one or more good synthesized channels. One or more bad synthesized channels may be abandoned.

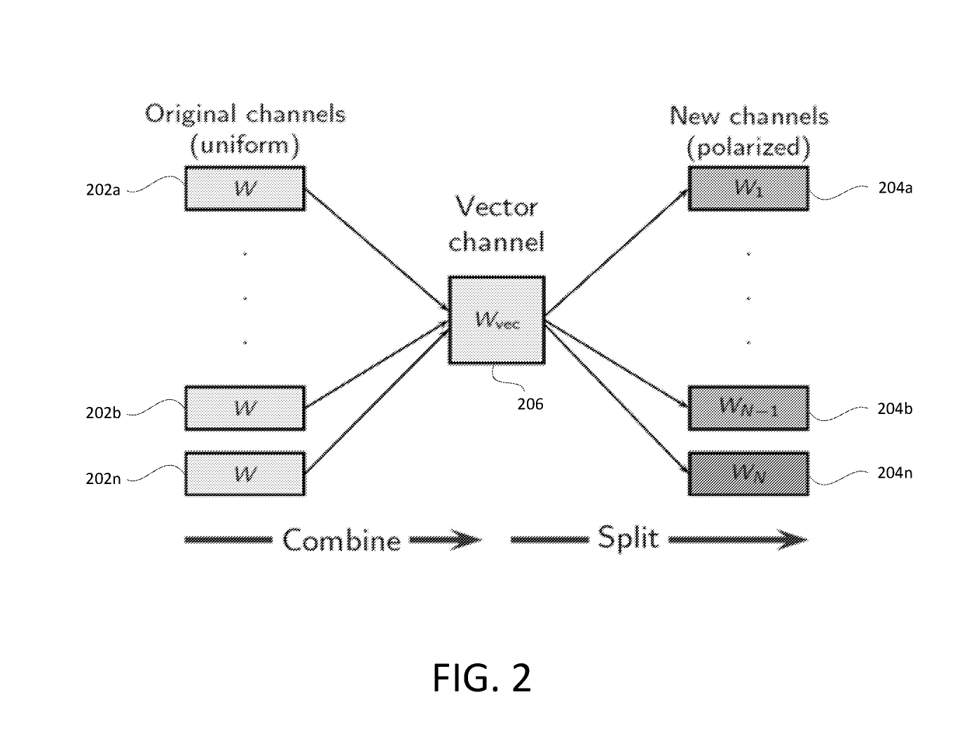

FIG. 2 depicts an example channel polarization. One or more uniform channels 202a, 202b, . . . , 202n (collectively referred to as 202) may be transformed into one or more polarized channels 204a, 204b, . . . , 204n (collectively referred to as 204). For example, one or more uniform channels 202 may be transformed into one or more polarized channels 204 using a vector channel 206. One or more independent copies of B-DMC may be transformed into one or more polarized channels. The one or more independent copies of B-DMC may be represented as N. The one or more polarized channels may be represented as N. The channel polarization may be performed in one or more stages. The one or more stages may include a combining stage and/or a splitting stage.

The combining stage may include linearly transforming one or more (e.g., source) bits (U₁, . . . , U_{N}) to one or more processed (e.g., polar coded) bits (X₁, . . . , X_{N}). The one or more source bits may be linearly transformed to the one or more processed bits using a one-to-one mapping. The one or more processed bits may be sent through one or more (e.g., N) independent B-DMC channels. The one or more processed bits being sent through the one or more independent B-DMC channels may result in a vector channel W_{VEC}: U^{N}→Y^{N}.

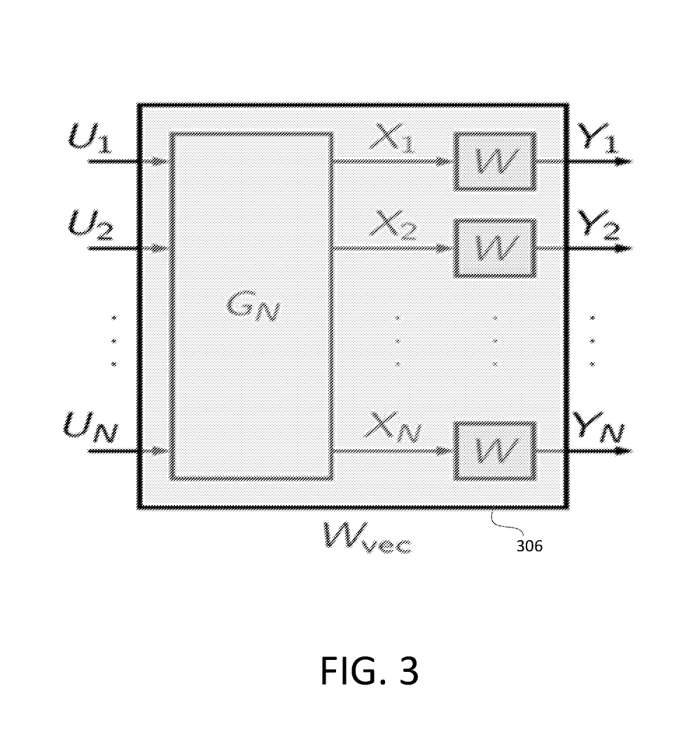

FIG. 3 depicts an example combining using a vector channel 306. The combining stage may be lossless and the vector channel may be defined as C(W_{VEC})=N·C(W). The combining stage may be lossless because of the one to one mapping.

The splitting stage may include splitting the vector channel W_{VEC} into (e.g., back to) N different channels (W₁, . . . , W_{N}). For example, the splitting stage may include splitting the vector channel W_{VEC} into N different channels (W₁, . . . , W_{N}), where Wᵢ:Uₜ→Y^{N}×Uⁱ⁻¹.

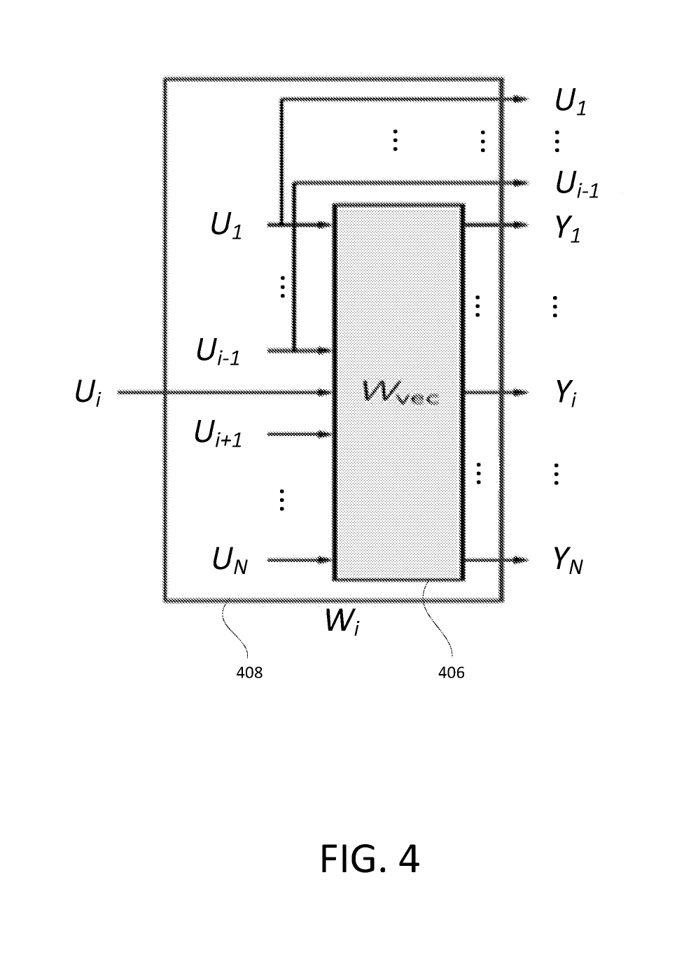

FIG. 4 depicts an example splitting using a vector channel 406. A combined vector channel, C(W_{VEC}) may be equal to the sum of one or more split channels 408, Wᵢ. For example, C(W_{VEC})=Σᵢ₌₁^{N}C(Wᵢ). A number of good channels among (W₁, . . . , W_{N}) may be close to I(W).

Multi-User Superposition Transmission (MUST) may be provided. MUST may include performing a superposed (e.g., combined) transmission of two or more WTRU signals onto one or more radio resources. The one or more radio resources may be the same radio resources. For example, MUST may include performing a superposed (e.g., combined) transmission of two or more WTRU signals onto one or more radio sources so that spectrum efficiency and/or throughput may be boosted. For example, MUST may include performing a superposed (e.g., combined) transmission of two or more WTRU signals onto one or more radio sources so that the spectrum efficiency and/or throughput may be boosted with the help of advanced receivers.

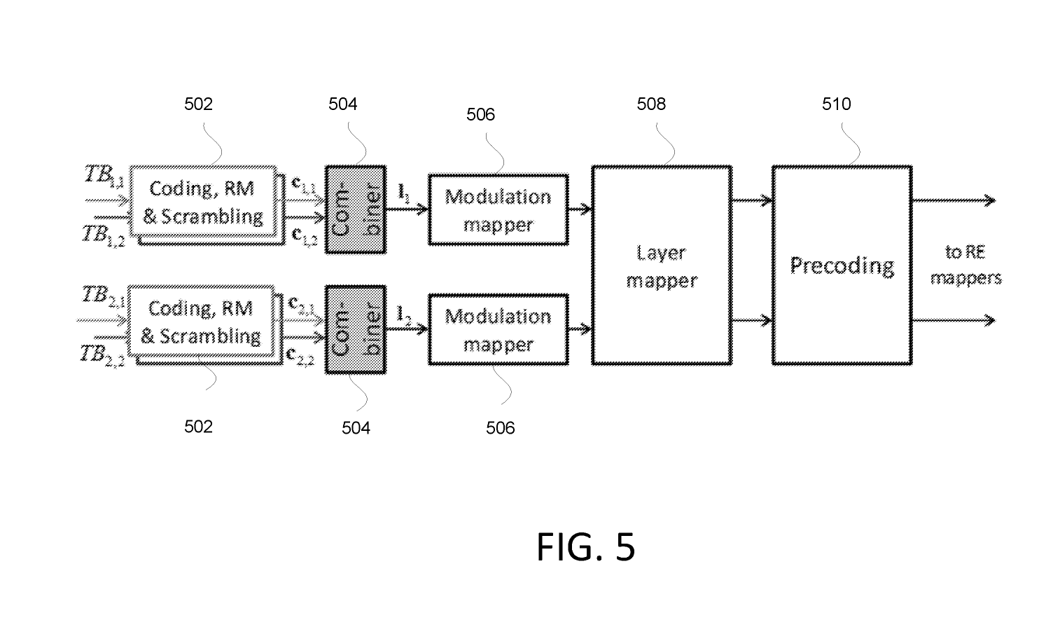

A combination of two or more WTRU signals may be performed at one or more levels in a physical layer processing. FIG. 5 depicts an example MUST. As shown in FIG. 5, the example MUST may include one or more of a coding, RM, & Scrambling 502, a combiner 504, a modulation mapping 506, a layer mapping 508, and/or a precoding 510. The example MUST shown on FIG. 5 may include combining 504 performed at the codeword level. For example, the two or more WTRU signals may be combined 504 after channel coding, rate matching, and/or scrambling 502.

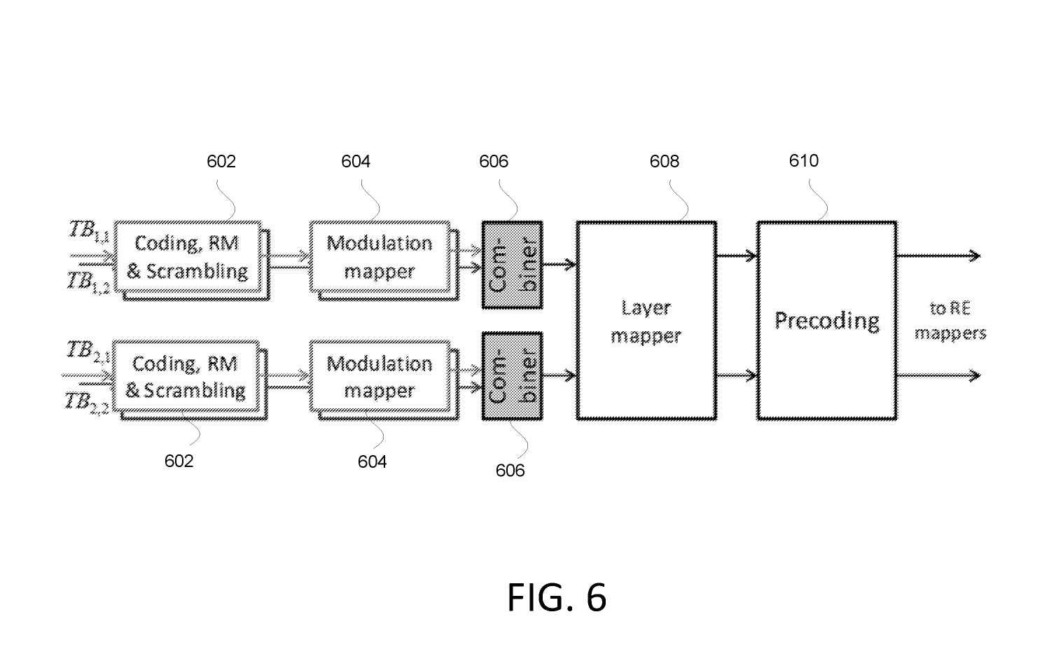

FIG. 6 depicts an example MUST with the combining 606 performed at the modulation mapping level. As shown in FIG. 6, the example MUST may include one or more of a coding, RM, & Scrambling 602, a modulation mapping 604, a combiner 606, a layer mapping 608, and/or a precoding 610. The combining 606 being performed at the modulation mapping level may be referred to as hierarchical modulation. One or more first WTRU (e.g., far WTRU) modulation symbols may be amplitude-weighted. For example, one or more first WTRU (e.g., far WTRU) modulation symbols may be amplitude-weighted by coefficient \sqrt{1−α}. One or more second WTRU (e.g., near WTRU) modulation symbols may be amplitude-weighted. For example, one or more second WTRU (e.g., near WTRU) modulation symbols may be amplitude-weighted by coefficient \sqrt{α}.

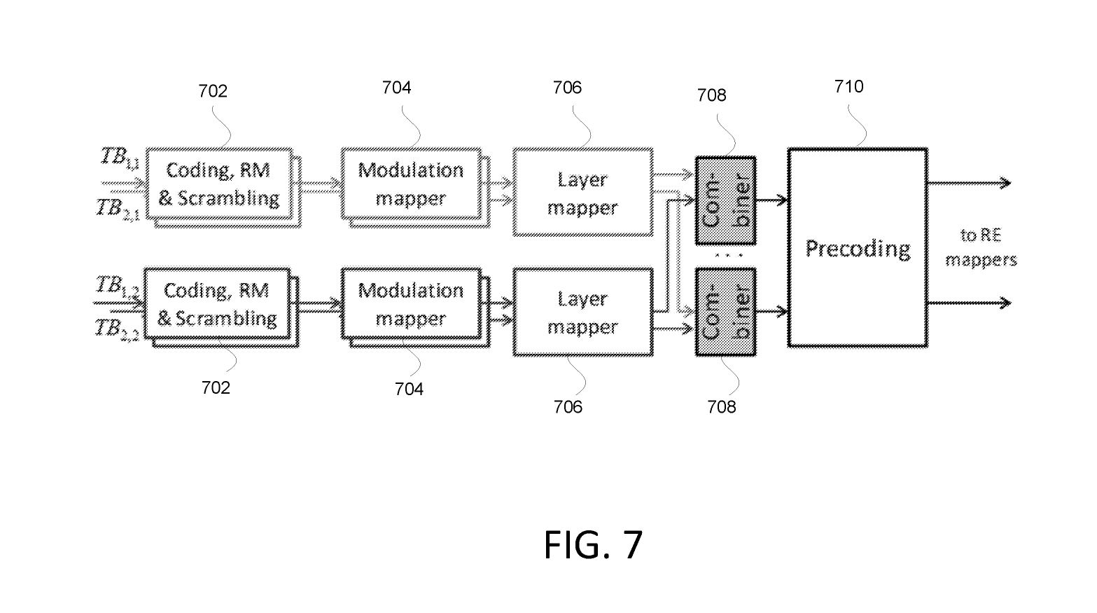

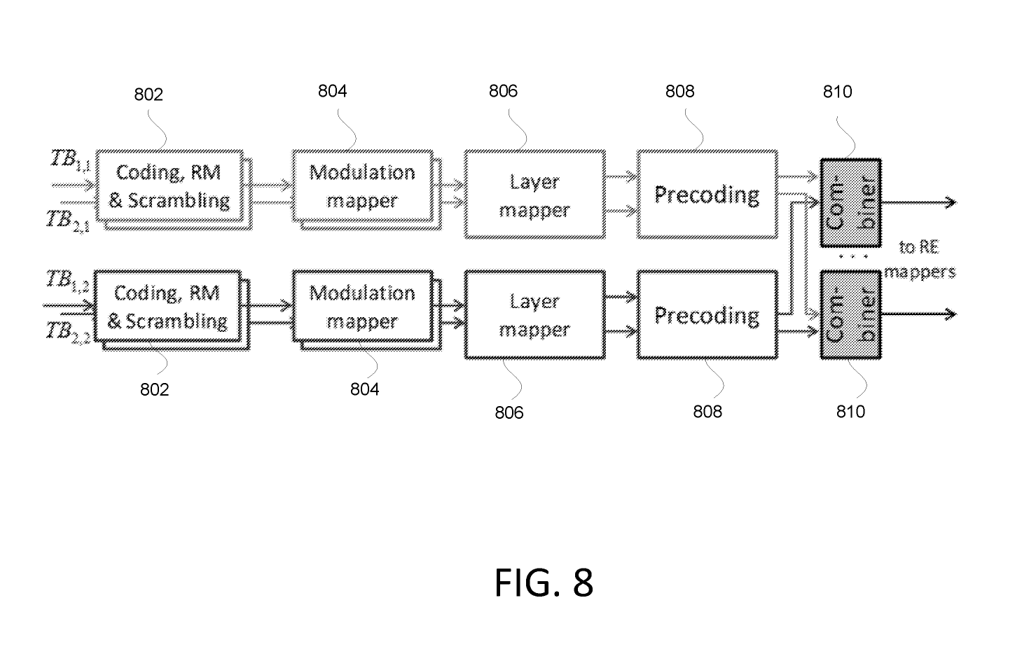

FIG. 7 depicts an example MUST with the combining 708 performed at the spatial layer level. As shown in FIG. 7, the example MUST may include one or more of a coding, RM, & Scrambling 702, a modulation mapping 704, a layer mapping 706, a combiner 708, and/or a precoding 710. FIG. 8 depicts an example MUST with the combining 810 performed after MIMO precoding. As shown in FIG. 8, the example MUST may include one or more of a coding, RM, & Scrambling 802, a modulation mapping 804, a layer mapping 806, a precoding 808, and/or a combiner 810. Precoding 808 (e.g., STBC precoding) may be performed on a first WTRU. Multiplexing may be performed on a second WTRU. For example, multiplexing may be performed on a second WTRU before the signals of the first WTRU and the second WTRU are combined.

Progressive image and/or scalable video encoders may employ a transmission mode. For example, progressive image and/or scalable video encoders may employ a transmission mode such that a source can be reconstructed with better quality. Progressive image and/or scalable video encoders may employ a transmission mode, such that a source can be reconstructed with better quality, as more bits are received. A progressive source may include a progressive image encoder and/or a scalable video encoder. One or more bits of the progressive source may be associated with a decreasing (e.g., steadily decreasing) importance later in the stream.

For reliable transmissions of one or more progressive sources over wireless channels, unequal error protection may be applied. For example, more important bits (e.g., bits earlier in the stream) may need stronger error protection. Less important bits (e.g., bits later in the stream) may need weaker error protection, e.g., than the more important bits.

The unequal error protection may be applied at the MIMO precoding level. For example, the more important bits may be precoded with Alamouti coding. The more important bits may be precoded with Alamouti coding for diversity gain. The less important bits may be precoded with spatial multiplexing. The less important bits may be precoded with spatial multiplexing for a high data rate. The unequal error protection may be performed at the modulation level. For example, the unequal error protection may be performed using hierarchical modulation. The more important bits may be modulated with one or more high constellation separations. The less important bits may be modulated with one or more lower constellation separations.

The unequal error protection may not be applied at the channel coding level. One or more input bits may not be prioritized. For example, one or more input bits may not be prioritized in traditional channel codes. The traditional channel codes may handle one or more of the input bits the same.

One or more prioritized source bits may be protected. The one or more prioritized source bits may be protected after channel coding. Multiple channel codes may be used for the one or more prioritized source bits. For example, multiple channel codes with the same, or different, coding rates may be used for the one or more prioritized source bits. This may complicate the communication system.

Implementation(s) with a single channel code may be provided herein, and may perform unequal protection on the one or more prioritized source bits.

Polarization may be performed. A synthesized channel may result from the polarization. The synthesized channel may be considered a good channel if, for example, it has a high capacity. For example, due to the polarization martingale, one or more good channels (e.g., each good channel) may have different channel capacities. The difference in channel capacities may be significant. For example, the difference in channel capacities may be significant for a smaller block size.

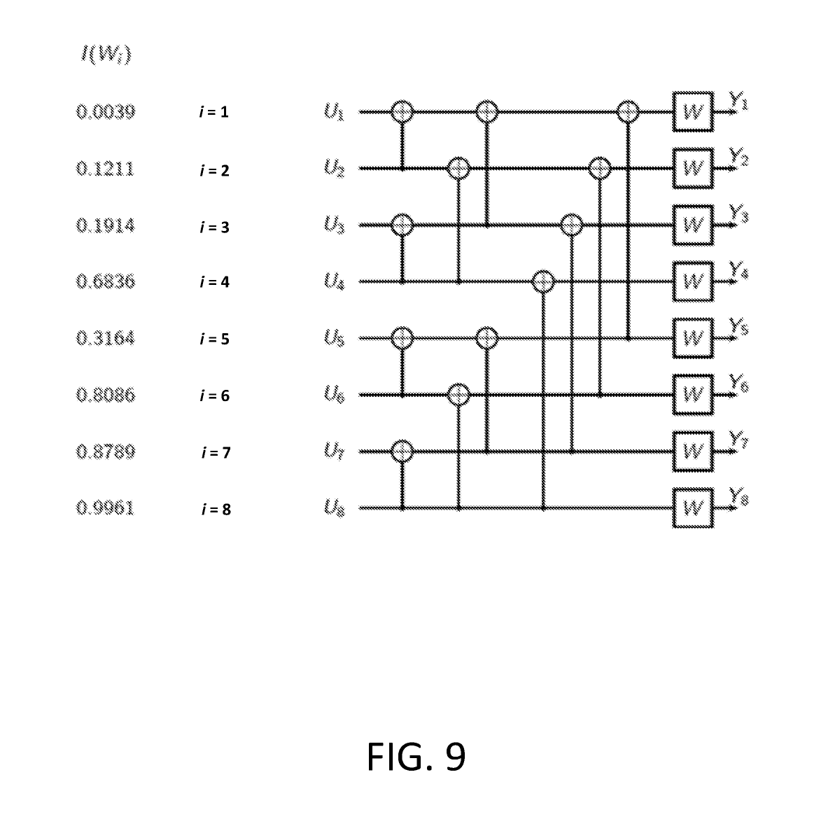

FIG. 9 depicts an example polar code. For example, an original channel W may be a Binary Erasure Channel (BEC) with an erasure probability ϵ=½ and/or a block length N=8. One or more capacities of the split channels may be determined, as shown in FIG. 9. The one or more capacities of the split channels may relate (e.g., directly relate) to the reliabilities of the split channels.

For example, as shown in FIG. 9, I(W₈)>I(W₇)>I(W₆)>I(W₄)>I(W₅)>I(W₃)>I(W₂)>I(W₁). As defined herein, I(W8) may be more reliable than I(W7), which may be more reliable than I(W6), which may be more reliable than I(W4), which may be more reliable than I(W5), which may be more reliable than I(W3), which may be more reliable than I(W2), which may be more reliable than I(W1). The BEC(½) may have a capacity of ½. A rate 1/2 polar code may be applied to achieve the capacity of ½. When the capacity is ½, the channels W₈, W₇, W₆, W₄ may be good channels. When the capacity is ½, the capacity of channel W₈ may be 0.9961 and/or the capacity of channel W₄ may be 0.6836. For example, the channel W₈ may be more reliable than the channel W₄.

Using polar codes to achieve a determined capacity may be applied if the source bits have different priorities and/or reliability requirements. For example, one or more source bits with higher priorit(ies) may be sent over one or more channels with higher capacities.

Polar coding may be performed on one or more prioritized source bits. For example, polar coding may be performed on progressive images and/or scalable video. One or more polar codes may be applied on the one or more prioritized source bits such that higher priority source bits may be more protected. In polar coding, one or more synthesized channels may be polarized with a ranked capacity. The ranked capacity of the one or more synthesized channels may relate (e.g., directly relate) to a ranked reliability of the one or more synthesized channels. The one or more synthesized channels may match the one or more prioritized source bits. Joint source and polar coding may include sending higher priority (e.g., more important) source bits to the one or more high capacity (e.g., high reliability) synthesized channels. Joint source and polar coding may include sending lower priority (e.g., less important) source bits to one or more lower capacity (e.g., lower reliability) synthesized channels.

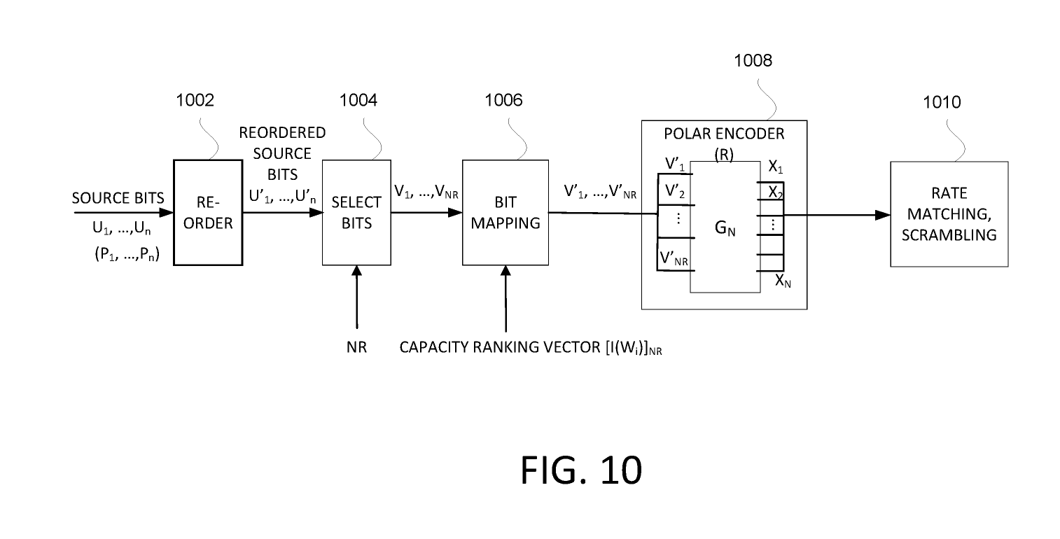

FIG. 10 depicts an example polar encoder 1008 applied on one or more source bits with different priorities. The different priorities may be represented by a plurality of different priority levels, P₁, . . . , Pₙ. For example, each of the one or more source bits Uᵢ may be associated with a priority level Pᵢ.

As shown in FIG. 10, joint source and/or polar coding (e.g., encoding and/or decoding) may be performed at a transmitter (e.g., a transmitting entity such as a network side device or a user side device). For example, joint source and/or polar coding may be performed at a transmitting WTRU. The joint source and/or polar coding may include one or more of a re-order component 1002, a select bits component 1004, a bit mapper component 1006, and/or a polar encoder component 1008.

The re-order component 1002 may be applied to one or more source bits. The re-order component 1002 may perform re-ordering in terms of the respective priorities of the one or more source bits. For example, n source bits U₁, . . . , Uₙ may be sent over one or more wireless channels. The respective priorities of the one or more source bits may be defined as P₁, . . . , Pₙ. For one or more progressive images, the one or more source bits may be defined as P₁>P₂ . . . >Pₙ. For other sources (e.g., scalable video), one or more un-ordered input bits may be included. The re-order component 1002 may arrange the one or more source bits U, . . . , Uₙ in the order of their priorities. One or more outputs of the re-order component 1002 may be denoted by U′₁, . . . , U′ₙ, where U′₁ may have the highest priority and U′ₙ may have the lowest priority.

The select bits component 1004 may be applied based on a coding rate R and/or a block size N of one or more polar codes. The select bits component 1004 may select NR bits from the n ordered source bits U′₁, . . . , U′ₙ. The NR bits may be set as the inputs to the polar encoder 1008. For example, the NR bits may be set as the inputs to the polar encoder 1008 after the next “bit-mapping” component.

If n≤NR, one or more (e.g., all) of the n bits may be selected.
If n>NR, the select bits component 1004 may select NR bits out of n inputs bits. For example, let

$$K = ⌈ \frac{n}{NR} ⌉ ,$$

where └x┘ may round me element of x up to the nearest integer. For the n inputs bits, there may be K output blocks. The K output blocks may include NR or less bits. The i-th block may include bits U′ⱼ. For example, the i-th block may include bits U′ⱼ, where j mod K=i. For example, when n=12 and NR=4, there may be K=3 output blocks. A first block may include the bits U′ᵢ, U′₄, U′₇, U′₁₂. A second block may include the bits U′₂, U′₅, U′₈, U′₁₁. A third block may include the bits U′₃, U′₆, U′₉, U′₁₂. One or more high priority source bits may be distributed (e.g., equally distributed) among different blocks. The one or more high priority source bits may be highly protected (e.g., more protected than lower priority source bits). For example, higher priority source bits may be more protected than lower priority source bits as a result of the higher priority source bits being polar encoded to a higher capacity channel than the lower priority source bits.
The bit-mapping component 1006 may map a block of NR bits to one or more corresponding ports of a polar encoder 1008. The mapping of the block of NR bits may be based on a capacity rank vector of one or more polar codes. For example, the mapping of the block of NR bits may be based on a capacity rank vector of one or more polar codes denoted as [I(Wᵢ)]. The capacity rank vector of one or more polar codes, denoted as [I(Wᵢ)], may relate (e.g., directly relate) to a reliability of the one or more polar codes. A first input bit (e.g., higher priority bit) may be mapped to a first polar encoder port, e.g., corresponding to a highest I(Wᵢ). A second input bit (e.g., lower priority bit than the first input bit) may be mapped to a second polar encoder port, e.g., corresponding to a second highest I(Wᵢ), etc.

The example polar code shown in FIG. 9 may be applied to one or more input bits. For example, the example polar code shown in FIG. 9 may be applied to 5 input bits V₁, V₂, V₃, V₄, V₅. As the synthesized channels with the capacities and/or reliabilities ranked as I(W₈)>I(W₇)>I(W₆)>I(W₄)>I(W₅), an output of the bit-mapping component may be represented as V₄, V₅, V₃, V₂, V₁. V₄ may be the input of the 4th synthesized channel; V₅ may be the input of the 5^{th} synthesized channel; V₃ may be the input of the 6th synthesized channel, V₂ may be the input of the 7^{th} synthesized channel, and V₁ may be the input of the 8^{th} synthesized channel.

The polar encoder component 1008 may include sending the one or more bit-mapped source bits through a main block of polar coding. The polar encoder component 1008 may generate a coded bit. For a systematic and/or a non-systematic polar code, NR bit-mapped source bits may be encoded into N channel coded bits X₁, . . . , X_{N}.

Rate matching 1010, constellation mapping, layer mapper and precoding, and/or the like may be performed after polar encoding.

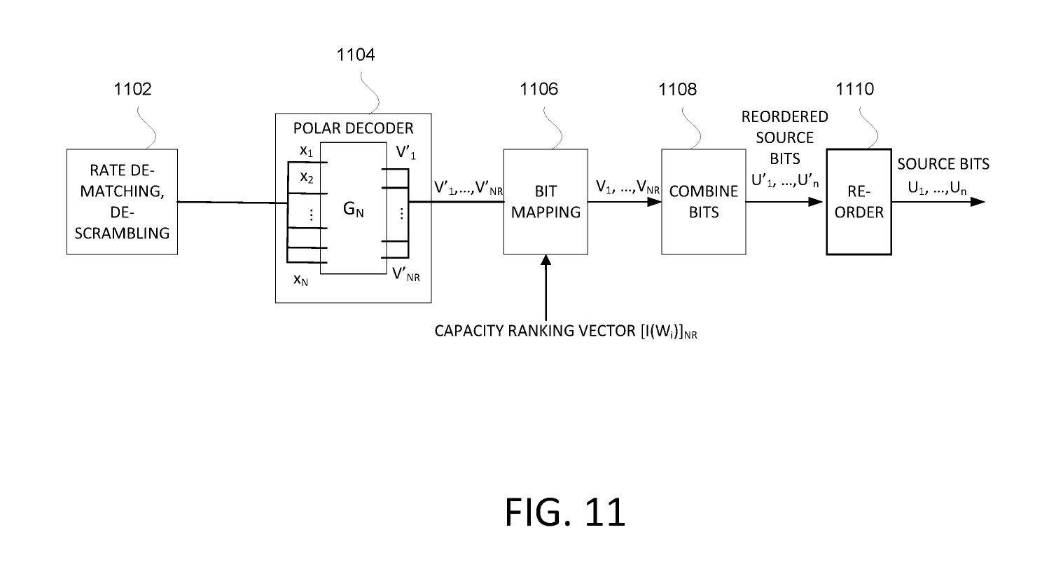

FIG. 11 depicts an example polar decoding of one or more source bits with priorities. As shown in FIG. 11, the joint source and polar decoding may include one or more of a rate de-matching, de-scrambling 1102, a polar decoder component 1104, a bit-mapping component 1106, a combine bits component 1108 and/or a re-order component 1110. The joint source and polar decoding may include one or more of a polar decoder component 1104, a bit-mapping component 1106, a combine bits component 1108 and/or a re-order component 1110 at the receiver.

The polar decoder component 1104 may include sending one or more scrambled polar coded bits Y₁, . . . , Y_{N} through a main block of a polar decoder. With the polar coding rate R, the NR decoded bits may be denoted by V′₁, . . . , V′_{NR}.

The bit-mapping component 1106 may include ranking two or more polar decoded bits 171, V′₁, . . . , V′_{NR}. The two or more polar decoded bits may be ranked based on a capacity rank vector of the polar codes [I(Wᵢ)]. For example, a first bit from the polar decoder 1104 corresponding to a highest I(Wᵢ) may be set as a first output bit; a second bit from the polar decoder 1104 corresponding to a second highest I(Wᵢ) may be set as the second output bit, etc. One or more outputs of the bit-mapping component 1106 may be denoted by V₁, . . . , V_{NR}.

The combine bits component 1108 may include combining one or more data blocks output from the polar decoder 1104. For example, there may be K data blocks. The K data blocks may have NR or less bits. V_{i,j}, 1≤i≤K, 1≤j≤NR may denote the j-th bit from the i-th data block. One or more outputs of the combine bits component 1108 may include re-ordered source bits U′₁, . . . , U′ₙ. For example, U′ₚ=V_{i,j}, i=p mod K, and

$$j = ⌊ \frac{p - 1}{K} ⌋ + 1 ,$$

where └x┘ may round the element of x down to the nearest integer.

For example, when K=3 and NR=4, U′₁=V_{1,1}; U′₂=V_{2,1}; U′₃=V_{3,1}; U′₄=V_{1,2}; U′₅=V_{2,2}; U′₆=V_{3,2}; U′₇=V_{1,3}; U′₈=V_{2,3}; U′₉=V_{2,3}; U₉=V_{3,3}; U′₁₀=V_{1,4}; U′₁₁=V_{2,4}; U₁₂=V_{3,4}. One or more output bits (e.g., U′₁, . . . , U′ₙ) may include the actual source bits, ranked in terms of their priorities.

The re-order component 1110 at the transmitter side may not reverse an operation. The respective priorities of the one or more source bits may be known as P₁, . . . , Pₙ. The operation may be as follows:

U₁=U′ᵢ may be set using the largest Pᵢ among the priority list. U₁=U′ⱼ may be set using the second largest Pᵢ among the priority list.

Combining may be performed at a channel coding level for MUST. As described herein, one or more MUSTs may be performed at a codeword level, a modulated symbol level, a spatial layer level, and/or a MIMO precoding level. One or more MUSTs may be performed at the channel coding level. For example, one or more MUSTs may be performed at the channel coding level when one or more polar codes are used.

A base station (BS) may send first data U_{1,1}, . . . , U_{1,n1} to a first WTRU and a BS may send second data U_{2,1}, . . . , U_{2,n2} to a second WTRU. A channel between the BS and the first WTRU may be better than a channel between the BS and the second WTRU. With MUSTs, the first WTRU's data may be superposed on the second WTRU's data. For example, the first WTRU's data may be superposed on the second WTRU's data so that the second WTRU may receive its data. The first WTRU may be able to receive one or both sets of data.

The data U_{2,1}, . . . , U_{2,n2} may need more error protection than the data U_{1,1}, . . . , U_{1,n1}. For example, the data U_{2,1}, . . . , U_{2,n2} may need more error protection than the data U_{1,1}, . . . , U_{1,n1} because the channel from base station to the second WTRU may be worse. The error protection may enable delivery (e.g., successful delivery). The error protection may be applied at the polar coding level.

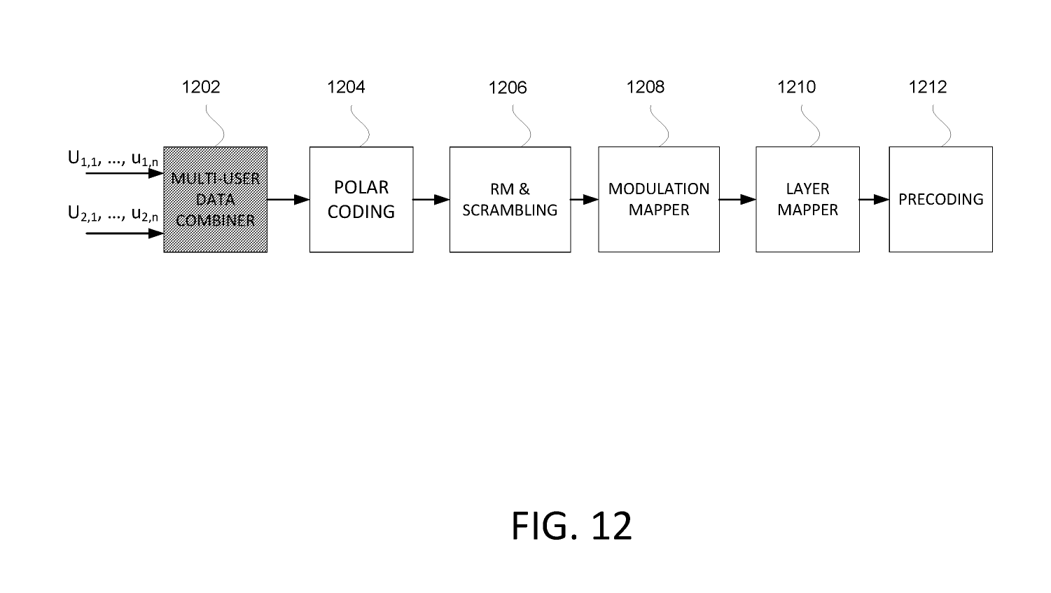

FIG. 12 depicts an example combining at a channel coding level. As shown in FIG. 12, the example combining may include a multi-user data combiner 1202, polar coding 1204, RM & scrambling 1206, modulation mapping 1208, layer mapping 1210, and/or precoding 1212. The example combining at the channel coding level may include a two-WTRU transmission system. For example, the example combining at the channel coding level may include a two-WTRU transmission system where the superposition is at the channel coding level. Data for a first WTRU and/or data for a second WTRU may be combined before passing to the polar code block 1204. In the multi-user data combiner 1202, one or more source bits may be arranged such that the data for the second WTRU may be mapped to one or more higher capacity synthesized channels. For example, one or more source bits may be arranged such that the data for the second WTRU may be mapped to one or more synthesized channels having a higher capacity than one or more channels used for the first WTRU.

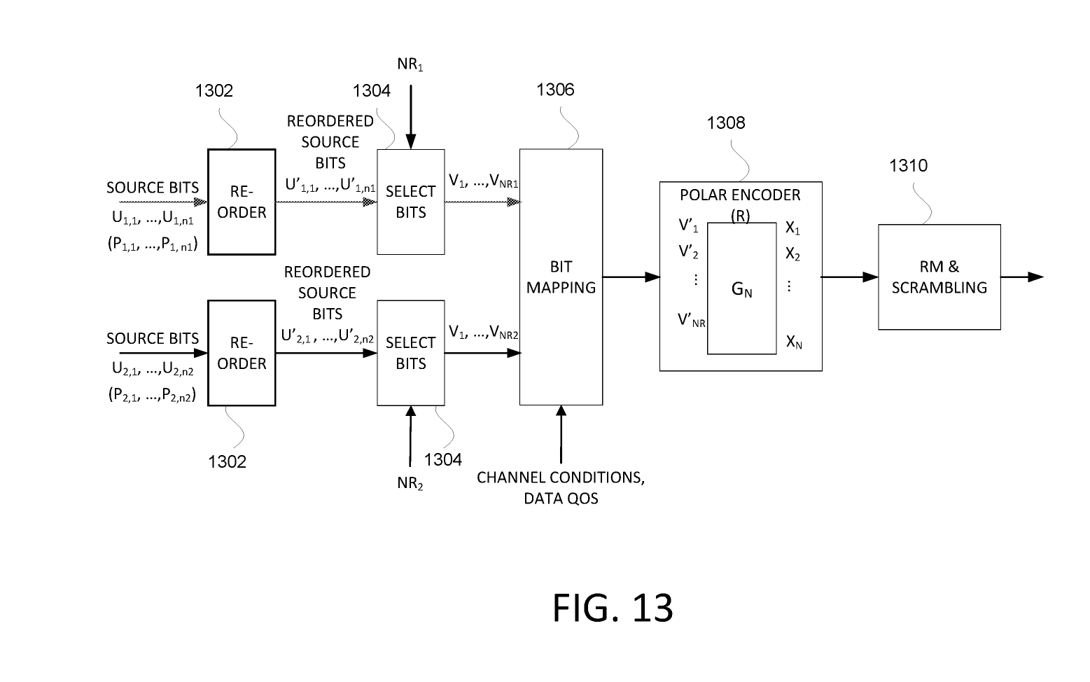

A multi-user data combiner (e.g., multi-user data combiner 1202) may comprise one or more components. For example, a multi-user data combiner may comprise re-order component 1302, select-bits component 1304, and/or bit mapping component 1306, shown in FIG. 13. As shown in FIG. 13, joint source and polar encoding at a transmitter may include one or more of a re-order component 1302, a select bits component 1304, a bit-mapping component 1306, a polar encoder component 1308, and/or a RM & scrambling 1310.

A re-order component 1302 may be assigned for a WTRU's data. For example, a WTRU (e.g., a first WTRU and/or a second WTRU) may send one or more source bits U_{1,1}, . . . , U_{1,n1} over one or more wireless channels. The priorities of the one or more source bits may be defined as P_{1,1}, . . . , P_{1,n1}. The re-order component 1302 may arrange the one or more source bits U_{1,1}, . . . , U_{1,n1} in an order based on the respective priorities. One or more outputs of the re-order component 1302 may be denoted by U′_{1,1}, . . . , U′_{1,n1}, where U′_{1,1} has a highest priority and U′_{1,n} has a lowest priority.

A WTRU may be associated with a select bits component 1304. For example, there may be one select-bits component 1304 per WTRU. A polar code may include a block size N and/or a coding rate R. Two WTRUs may share the same polar code. The two WTRUs may experience a lower coding rate than R. For example, a first coding rate for a first WTRU may be R₁, and/or a second coding rate for a second WTRU may be R₂. The coding rate R may be defined as R₁+R₂=R.

The determination of R₁ and/or R₂ may be based on a WTRU priority. The determination of R₁ and/or R₂ may be based on an amount of data for each WTRU to be sent. The determination of R₁ and/or R₂ may be based on a priority of the data for each WTRU to be sent. R₁ and R₂ may be different values.

For the first WTRU, the select-bits component 1304 may select NR₁ bits from one or more ranked source bits U′_{1,1}, . . . , U′_{1,n1}. Given the n₁ source bits, the first WTRU may generate

$${K}_{1} = ⌈ \frac{{n}_{1}}{{NR}_{1}} ⌉$$

output blocks. Output block may include NR₁ or less bits. The i-th block may include bits U′_{1,j} bits, where j mod K₁=i. The second WTRU may select from the one or more ranked source bits and/or generate one or more output blocks.

With a first block of NR₁ bits for a first WTRU and/or a second block of NR₂ bits from a second WTRU, the bit-mapping component 1306 may map the first block and/or the second block to the corresponding input ports of a polar encoder 1308. The mapping may be based on a capacity rank vector of one or more polar codes, denoted as [I(Wᵢ)].

The mapping may depend on one or more channel conditions of a first WTRU and/or a second WTRU.

A first channel from a BS to the first WTRU may have a better condition than a second channel from a BS to the second WTRU. The second WTRU's data may need higher protection than the first WTRU's data. For example, the second WTRU's data may be mapped to one or more polar encoder ports with a higher I(Wᵢ). The first WTRU's data U′_{1,1}, . . . , U′_{1,n1} may be mapped to one or more polar encoder ports with lower I(Wᵢ).

The mapping may depend on a first QoS of first data associated with the first WTRU. The mapping may depend on a second QoS of second data associated with the second WTRU.

The first WTRU may include data with a high or low QoS requirement and/or the second WTRU may include data with a high or low QoS requirement. For example, if the first WTRU includes data with a high QoS requirement and the second WTRU includes data with a low QoS requirement, the first WTRU's data U′_{1,1}, . . . , U′_{1,n1} may be mapped to the one or more polar encoder ports with a higher I(Wᵢ). The second WTRU's data U′_{2,1}, . . . , U′_{2,n2} may be mapped to the one or more polar encoder ports with lower I(Wᵢ).

The mapping may depend on one or more of the conditions described herein. For example, the first WTRU may be associated with a better channel condition than the second WTRU, and/or the first WTRU's data may have a lower QoS requirement than the second WTRU. The bit-mapping component may determine whether the first WTRU's data needs a higher protection and/or whether the second WTRU's data needs a higher protection. The bit-mapping component may determine whether the first WTRU's data and the second WTRU's data need the same protection.

A WTRU's data may need higher protection than another WTRU's data. For example, a WTRU's data may need higher protection than another WTRU's data according to a predefined weight. The first WTRU's data U′_{1,1}, U′_{1,2}, U′_{1,3} may be mapped to the three polar encoder ports with the three highest I(Wᵢ). The second WTRU's data U′_{2,1}, U′_{2,2} may be mapped to the two polar encoder ports with the next two highest I(Wᵢ). The first WTRU's data U′_{1,4}, U′_{1,5}, U′_{1,6} may be mapped to the three polar encoder ports with the next three highest I(Wᵢ). The second WTRU's data U′_{2,3}, U′_{2,4} may be mapped to the two polar encoder ports with the next two highest I(W₁), etc. The first WTRU's data may be more protected than the second WTRU's data.

When one or more (e.g., both) of the data need the same protection, the data may be mixed and/or U′_{1,1}, U′_{2,1}, U′_{1,2}, U′_{2,2}, U′_{1,3}, U′_{2,3} . . . may be mapped to the polar encoder ports with high I(Wᵢ) in that order.

A mixed bit-mapping algorithm may be sent to one or more receivers. For example, a mixed bit-mapping algorithm may be sent to one or more receivers so that the one or more receivers may know which bits belong to them.

The polar encoder component 1308 may include one or more bit-mapped source bits passed through a main block of polar coding. The main block of polar coding may generate a coded bit. For a non-systematic polar code, NR bit-mapped source bits may receive N channel coded bits X₁, . . . , X_{N}. For a systematic polar code, a bit-mapped source bit may generate N channel coded X₁, . . . , X_{N} bits.

Rate matching, constellation mapping, layer mapping, and/or precoding may be performed after the polar encoder.

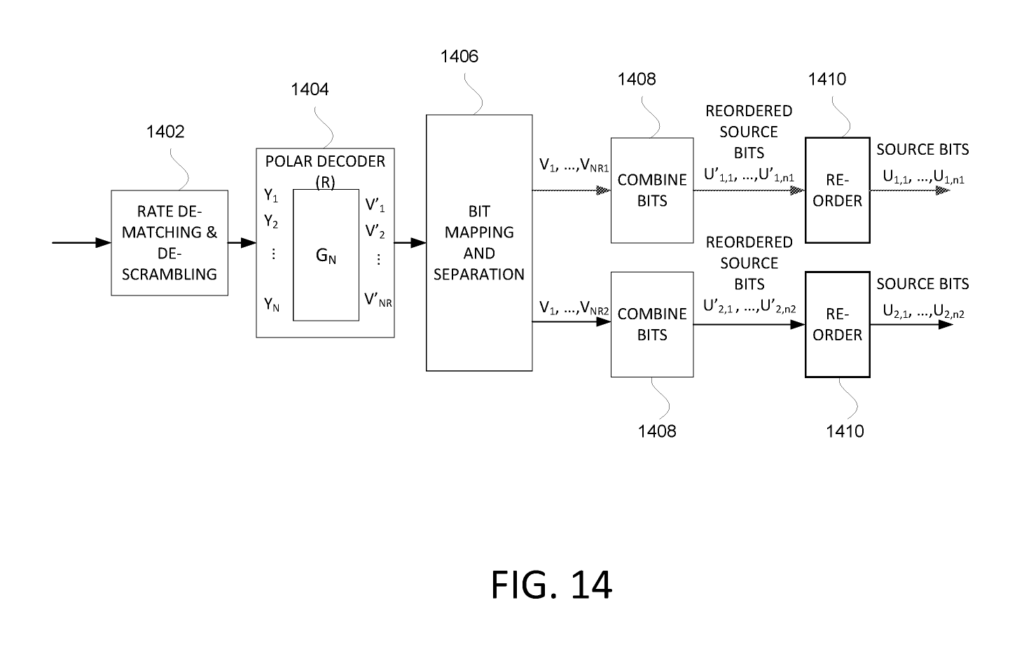

FIG. 14 depicts an example detailed multi-user data separator and polar decoder. As shown in FIG. 14, a joint source and polar decoding at a receiver may include one or more of a rate de-matching & de-scrambling 1402, polar decoder component 1404, a bit-mapping and separation component 1406, a combine bits component 1408, and/or a re-order component 1410.

The polar decoder component 1404 may include sending one or more scrambled polar coded bits Y₁, . . . , Y_{N} through the main block of a polar decoder. The NR decoded bits may be denoted by V′₁, . . . , V′_{NR}. For example, when the polar coding rate is R, the NR decoded bits may be denoted by V′₁, . . . , V′_{NR}.

The bit-mapping and separation component 1406 may rank one or more polar decoded bits V′₁, . . . , V′_{NR}. For example, the bit-mapping and separation component 1406 may rank one or more polar decoded bits V′₁, . . . , V′_{NR}, based on the capacity rank vector of the polar codes [I(Wᵢ)]. The bit from the polar decoder 1404 corresponding to the highest I(Wᵢ) may be set as a first bit V₁; the bit from the polar decoder 1404 corresponding to the second highest I(Wᵢ) may be set as the second output bit V₂, etc. The ranking of the one or more polar decoded bits may result in a bit sequence V₁, . . . , V_{NR}.

The bit sequence may include data from a first WTRU and/or a second WTRU. The bit-mapping and separation component 1406 may separate the data between the first WTRU and the second WTRU. The bit-mapping and separation component 1406 may need an algorithm (e.g., the algorithm applied by the transmitter) to mix the data. For example, in order to separate the first WTRU's data from the second WTRU's data the bit-mapping and separation component 1406 may need an algorithm to mix the data. One or more outputs of the bit-mapping and separation component 1406 may include a two data sequence, one data sequence for the first WTRU: V₁, . . . , V_{NR}_{₁}, and another data sequence for the second WTRU: V₁, . . . , V_{NR}_{₂}.

The combine bits component 1408 may combine two or more data blocks output from the polar decoder 1404. For example, there may be K data blocks. The K data blocks may have NR or less bits. Let V_{1,j}, 1≤i≤K, 1≤j≤NR, denote the j-th bit from the i-th data block. One or more outputs of the combine bits component 1408 may include one or more re-ordered source bits U′₁, . . . , U′ₙ. Here, U′ₚ=V_{i,j}, i=p mod K, and

$$j = ⌊ \frac{p - 1}{K} ⌋ + 1.$$

The re-order component 1410 may reverse the polar coding. For example, the re-order component 1410 may reverse the polar coding similar to the re-order component at the transmitter side. One or more priorities of the original source bits may be known at the decoder side as P_{1,1}, . . . , P_{1,n} and/or P_{2,1}, . . . , P_{2,n}.

The polar coding described herein may be extended to more than two WTRUs.

The ranking of the one or more synthesized channels may be unaffected by a capacity of an original channel. For example, the ranking of the one or more synthesized channels after polar coding may be unaffected by a capacity of an original channel. A difference between the first WTRU and the second WTRU may be that a corresponding original channel W may have different capacities. One or more synthesized channel capacities may depend on an original channel capacity. Ranking of the one or more synthesized channel capacities may be independent of the original channel capacity.

As shown in FIG. 9, an original channel for a first WTRU may include a BEC with erasure probability 0.3. The original channel for the second WTRU may include a BEC with an erasure probability of 0.5. One or more corresponding capacities of synthesized channels for the second WTRU may be determined as shown in FIG. 9. The one or more corresponding capacities of synthesized channels for the first WTRU may be calculated as I(W₁)=0.0576; I(W₂)=0.4226; I(W₃)=0.5475; I(W₄)=0.9323; I(W₅)=0.6857; I(W₆)=0.9705; I(W₇)=0.9839; I(W₈)=0.9999. The same ranking of the synthesized channels may be performed for the first WTRU as the second WTRU, I(W₈)>I(W₇)>I(W₆)>I(W₄)>I(W₅)>I(W₃)>I(W₂)>I(W₁).

A polar code may include a fixed coding rate and/or block size. One or more multi-user transmissions may result in a reduced maximum coding rate for each user. For example, one or more multi-user transmissions may result in a reduced maximum coding rate for each user when comparing with the single-user transmissions, as described herein. A polar code may include a coding rate R. In a single WTRU transmission case, the maximum coding rate for the single WTRU may be R. For the multi-user transmission case, the maximum coding rate for a WTRU may be less than R. For example, the maximum coding rate for a WTRU may be less than R as long as the other WTRUs have data to transmit.

The reduced maximum coding rate for a WTRU may be associated with the reduced data rate for a WTRU.

Two or more polar encoders may assign WTRUs to encoders. A WTRU's data may be split into segments. The segments may be assigned to one or more encoders. For example, the segments may be assigned to one or more encoders according to the priority of the segments. Polar encoding may be combined with allocation of resource blocks and/or PRBs to a WTRU. For example, polar encoding may be combined with allocation of resource blocks and/or PRBs to a WTRU to match a desired date rate. A larger size polar code (e.g., with larger code block length) may be shared by WTRUs without decreasing the data rate of the WTRU. Data may be split into two or more segments. The two or more segments may be sent in one or more time instances and/or TTIs. For example, the two or more segments may be sent in one or more time instances and/or TTIs such that the desired data rate may be met. MIMO may be applied with two or more data streams per WTRU. A WTRU's data may be split and/or transmitted in two or more data streams. For example, a WTRU's data may be split and/or transmitted in two or more data streams to meet the required data rate.

The block size of a polar code may be fixed. For example, the block size of a polar code may be fixed as N. If the block size of the polar code is fixed as N, a lowest coding rate of the WTRU in the single-user transmission case may be represented as 1/N. The lowest coding rate may not change. For example, the lowest coding rate may not change for a WTRU in the multi-user transmission case. In the single-user transmission case, one or more input ports may be frozen to a constant value. For example, one or more input ports, other than an input port with the WTRU's data, may be frozen to a constant value. In the multi-user transmission case, the input ports may not be frozen to a constant value. For example, the input ports, other than the one with a WTRU's data, may not be frozen to a constant value. The unfrozen value (or non-constant value) may correspond to data from one or more WTRUs. The multi-user transmission scenario may be associated with a lower link quality and/or a high outage probability. The data of a WTRU in the time domain may be repeated. For example, the data of a WTRU in the time domain may be repeated for different time instances and/or slots. The data of a WTRU in the time domain may be repeated for different time instances and/or slots such that the coherent gain may be achieved and/or the link quality may be enhanced to a level (e.g., the required level).

An output of the polar encoder may include a mixture of one or more WTRU signals. For example, when multiple users share a polar encoder, an output of the polar encoder may include a mixture of one or more WTRU signals. The one or more WTRUs may apply a modulation scheme (e.g., the same modulation scheme). WTRUs may apply one or more modulation schemes.

One or more WTRUs with the same modulation order and/or modulation scheme may be grouped together. One or more WTRUs with the same modulation order and/or modulation scheme may be scheduled to share a polar encoder (e.g., the same polar encoder). One or more minimum modulation orders from one or more WTRUs may share a polar encoder.

The processes described above may be implemented in a computer program, software, and/or firmware incorporated in a computer-readable medium for execution by a computer and/or processor. Examples of computer-readable media include, but are not limited to, electronic signals (transmitted over wired and/or wireless connections) and/or computer-readable storage media. Examples of computer-readable storage media include, but are not limited to, a read only memory (ROM), a random access memory (RAM), a register, cache memory, semiconductor memory devices, magnetic media such as, but not limited to, internal hard disks and removable disks, magneto-optical media, and/or optical media such as CD-ROM disks, and/or digital versatile disks (DVDs). A processor in association with software may be used to implement a radio frequency transceiver for use in a WTRU, terminal, base station, RNC, and/or any host computer.

1-22. (canceled)

23. A transmitter entity, comprising:
a processor configured to:
order source bits based on respective priorities of the source bits;
interleave the ordered source bits into a plurality of blocks, wherein a number of blocks comprising the plurality of blocks is determined based on a code rate, a polar code code size, and a number of the ordered source bits;
map respective ordered and interleaved source bits in the plurality of blocks to respective polar coder ports, wherein the respective ordered and interleaved source bits in the plurality of blocks are mapped to the respective polar coder ports based on a respective priority of each ordered and interleaved source bit, and wherein a respective higher priority bit in a respective block is encoded to a higher capacity channel than a lower priority bit in the respective block; and
perform polar encoding of the mapped bits.

24. The transmitter entity of claim 1, wherein being configured to interleave the ordered source bits comprises being configured to change a sequence of the ordered source bits.

25. The transmitter entity of claim 1, wherein bits of the ordered and interleaved source bits are equally distributed among each of the plurality of blocks based on the respective priority of each ordered and interleaved source bit.

26. The transmitter entity of claim 1, wherein the transmitter entity is a user device, and wherein the user device is a WTRU.

27. The transmitter entity of claim 23, wherein the source bits comprise first source bits of a first user and second source bits of a second user.

28. The transmitter entity of claim 23, wherein the transmitter entity is a network device, and wherein the network device is a base station, evolved node-B (eNodeB), or gNB.

29. The transmitter entity of claim 23, wherein the processor is configured to transmit the polar encoded bits.

30. The transmitter entity of claim 29, wherein the processor is configured to perform, after polar encoding, at least one of rate matching, constellation mapping, or layer mapper and precoding.

31. A method comprising:
ordering source bits based on respective priorities of the source bits;
interleaving the ordered source bits into a plurality of blocks, wherein a number of blocks comprising the plurality of blocks is determined based on a code rate, a polar code code size, and a number of the ordered source bits;
mapping respective ordered and interleaved source bits in the plurality of blocks to respective polar coder ports, wherein the respective ordered and interleaved source bits in the plurality of blocks are mapped to the respective polar coder ports based on a respective priority of each ordered and interleaved source bit, and wherein a respective higher priority bit in a respective block is encoded to a higher capacity channel than a lower priority bit in the respective block; and
performing polar encoding of the mapped bits.

32. The method of claim 31, wherein interleaving the ordered source bits comprises changing a sequence of the ordered source bits.

33. The method of claim 31, wherein bits of the ordered and interleaved source bits are equally distributed among each of the plurality of blocks based on the respective priority of each ordered and interleaved source bit.

34. The method of claim 31, wherein a transmitting entity is a user device, and wherein the user device is a WTRU.

35. The method of claim 31, wherein the source bits comprise first source bits of a first user and second source bits of a second user, and wherein a transmitting entity is a network device, and wherein the network device is a base station, evolved node-B (eNodeB), or gNB.

36. The method of claim 31, further comprising transmitting the polar encoded bits.

37. The method of claim 36, further comprising performing, after polar encoding, at least one of rate matching, constellation mapping, or layer mapper and precoding.
